(19) United States
(12) Patent Application Publication
(10) Pub. No.: US 2003/0047209 A1
(43) Pub. Date: Mar. 13, 2003

(54) Photovoltaic power generation system with storage batteries

(75) Inventors: Atsushi Yanai, Kobe-shi (JP); Yoshifumi Magari, Kobe-shi (JP); Katsuhiko Shinyama, Kobe-shi (JP); Atsuhiro Funahashi, Osaka (JP); Toshiyuki Nouma, Kobe-shi (JP); Ikuo Yonezu, Kobe-shi (JP); Ryuuzou Hagihara, Kobe-shi (JP); Takeo Ishida, Kobe-shi (JP); Osamu Oota, Osaka (JP)

Correspondence Address: ARMSTRONG,WESTERMAN & HATTORI, LLP, 1725 K STREET, NW., SUITE 1000, WASHINGTON, DC, 20006, US

(73) Assignee: SANYO ELECTRIC CO., LTD., Moriguchi-shi (JP)

(21) Appl. No.: 10/231,096

(22) Filed: Aug. 30, 2002

(30) Foreign Application Priority Data
Aug. 31, 2001 (JP) 264837/2001

(51) Int. Cl. H01L 31/00

(52) U.S. Cl. 136/291; 136/293; 136/244

(57) ABSTRACT

An object of the present invention is to provide a system capable of reducing optimally peak demand for power by using small capacity storage batteries.

The present invention was made to provide a photovoltaic power generation system which links with a utility power system, feeds electric power generated by a solar cell device to an inverter in order to convert the electric power into alternating current, and supplies the alternating current to a power consumption section. The photovoltaic power generation system comprises storage batteries for storing electric power and a switch control device for switching to output electric power from the solar cell device to the storage batteries or the inverter. Also the photovoltaic power generation system controls discharge of the electric power stored in the storage batteries with reference to a specific period of high power demand represented by a fluctuation curve of power demand, and supplies the electric power from the storage batteries along with generation power from the solar cell device to the inverter.

### BACKGROUND OF THE INVENTION

1. Field of the Invention

This invention relates to a photovoltaic power generation system having storage batteries, more particularly to a photovoltaic power generation system with storage batteries capable of optimally outputting electric power in accordance with a peak period of demand for power by controlling power output on the basis of a fluctuation curve of power demand.

2. Description of Prior Art

A demand curve for electric power reaches the peak in the daytime, while descending significantly at night. Year after year, such demand for power has been widening the gap of the load between night and day and between seasons. With an increase in demand for air-cooling system in summer, there is a growing demand for electric power at the peak period in the daytime. In order to prevent the possibility of power failure and so on due to electric power shortages, it is necessary to reserve a certain amount of power in preparation for maximum demand power.

Power demand varies depending on the season and time of day. FIG. 12 shows a typical load curve in Tokyo. Note that the values in ordinate are normalized. As shown in FIG. 12, power demand greatly changes with season and time of day. If we build power plants to reserve electric power to meet the maximum power demand, the power plants will be wasted at other time and season.

In consideration of recent global environmental issues, it is unfavorable to unnecessarily build large power plants dependent on fossil fuel and nuclear energy.

On the other hand, solar energy shining down to the earth is as much as 42 trillion kcal per second, which is about one hundred times the total amount of annual energy demand of the world. There is no reason not to use such an enormous amount of solar energy and actually a photovoltaic power generation system receives attention to obtain electric power from solar energy.

However, full use of solar energy cannot be made under the influences of season, time, place and weather. Now the average amount of solar radiation energy in Japan is 3.84 kWh per square meter a day. If a solar cell device generates electric power with the amount of solar radiation energy, electric power of 0.38 kWh per square meter a day can be obtained on the assumption that the conversion efficiency of solar cell is 10%.

In recent years, a photovoltaic power generation system, in which a solar cell device is installed on a roof and generates power to cover power consumption during day time as well as selling surplus power to electric power companies, is in practical use. Currently many of the photovoltaic power generation systems have a nominal power generating capacity of 3 kW. Under the above-mentioned condition of solar radiation, the photovoltaic power generation system of 3 kW can generate power of about 2700 kWh a year.

Supposed that about 20 million households in Japan install the photovoltaic power generation system of 3 kW, 54 billion kWh of electric power can be obtained per year. The amount of electric power is equivalent to about 6 percent of the total power generation in Japan. Besides the photovoltaic power generation system can generate more electric power in summer due to a greater amount of solar radiation.

Thus it is expected to cut back commercial power consumption especially at the peak period of power demand in summer by means of effective use of electric power generated by the photovoltaic power generation system.

Peak demand for power, however, would not be satisfied by simple use of electric power generated by the photovoltaic power generation system because the peak period of power demand in summer differs for a few hours from the peak period of solar radiation intensity. Therefore, commercial power would be still required at the peak period of power demand.

In Japanese Patent Publication No.252671/1993 (Int. Cl. H02J 7/35), a control system for photovoltaic power generation is proposed. The photovoltaic power generation system supplies peak power of the system at the time of peak demand of commercial power by charging a battery with electric power generated by the solar cell and combining the electric power, with a predetermined time lag, with commercial power.

According to the system, commercial power corresponding to the rated output of the photovoltaic power generation system can be reduced at the peak period of power demand. The system, however, needs to charge the battery with power generated until the peak of solar radiation in order to delay outputting the power for a predetermined time, thereby leading an issue that the battery must have a large capacity.

Also, as shown in the load curve of FIG. 12, the peak period of power demand varies by season. The only predetermined time lag cannot help meet seasonal power demand. Further, in Hokkaido (cold district) where home lightning is turned on while factories are working because sun sets early in winter and heating appliances are used a lot because of snow and cold wave, power demand is at maximum in winter, unlike other regions such as Tokyo and Osaka (mild districts). The only predetermined time lag of photovoltaic power output would not contribute to reduce commercial power consumption at the period of maximum power demand in such a region.

With the consideration of the above mentioned circumstances, an object of this invention is to provide a system capable of optimally reducing commercial power consumption at the peak period of power demand by using small capacity storage batteries and combining power discharged from the batteries with photovoltaic power only at the peak period of power demand.

### SUMMARY OF THE INVENTION

The present invention was made to provide a photovoltaic power generation system which feeds electric power generated by a solar cell device to an inverter in order to convert the electric power into alternating current and supplies the alternating current to a power consumption section. The photovoltaic power generation system comprises storage batteries for storing electric power. Also the photovoltaic power generation system controls the discharge of electric power stored in the storage batteries with reference to certain time period of high power demand represented by a fluctuation curve of power demand, and supplies the electric power from the storage batteries along with generation power from the solar cell device to the inverter.

Electric power for charging the storage batteries may be selected from either electric power generated by a solar cell device during the off-peak period of power demand after sunrise or electric power supplied from a utility power system during the night, or both.

Also the present invention was made to provide a photovoltaic power generation system which links with a utility power system, feeds electric power generated by a solar cell device to an inverter in order to convert the electric power into alternating current, and supplies the alternating current to a power consumption section. The photovoltaic power generation system comprises storage batteries for storing electric power and switch control means for switching to output electric power from the solar cell device to the storage batteries or the inverter. Also the photovoltaic power generation system controls the storage batteries to be charged with either electric power generated by a solar cell device at the off-peak period of power demand after sunrise or electric power transmitted from the utility power system during night, or both, and to discharge of the electric power stored in the storage batteries with reference to a specific period of high power demand represented by a fluctuation curve of power demand, and supplies the electric power from the storage batteries along with generation power from the solar cell device to the inverter.

Further the present invention was made to provide a photovoltaic power generation system which links with a utility power system, feeds electric power generated by a solar cell device to the inverter to convert the electric power into alternating current and supplies the alternating current to a power consumption section. The photovoltaic power generation system comprises storage batteries for storing electric power and control means for controlling charge and discharge of the storage batteries. Also the photovoltaic power generation system controls the storage batteries to be charged with either electric power generated by a solar cell device at the off-peak period of power demand after sunrise or electric power transmitted from the utility power system during night, or both, and to discharge the electric power stored in the storage batteries with reference to a specific period of high power demand represented by a fluctuation curve of power demand, and supplies the electric power from the storage batteries along with generation power from the solar cell device to the inverter.

Given that sunrise is 0% and sunset is 100% when the time range between sunrise and sunset is expressed as a percent, the certain time period in which power demand is high is in a range from 40 to 100%.

The time period in which electric power is discharged from the storage batteries and combined with power generated by the solar cell device is at the off-peak period of power generation of the solar cell device as well as the peak period of power demand. Given that sunrise is 0% and sunset is 100% when the time range between sunrise and sunset is expressed as a percent, such a period of time is in a range from 55 to 85%.

The photovoltaic power generation device can control an amount of the charging power for the storage batteries so that the total amount of power generated by the solar cell device and power discharged from the storage batteries at the peak period of power demand is equivalent to or more than the maximum amount of power generated by the solar cell device until the time represented by 55%, given that sunrise is 0% and sunset is 100% when the time range between sunrise and sunset is expressed as a percent.

Given that sunrise is 0% and sunset is 100% when the time range between sunrise and sunset is expressed as a percent, the time period in which the batteries are charged within the off-peak period of power demand may be in a range from 0 to 40%.

The capacity of the storage battery for constant use may be in a range from 0.1 to 0.8 kWh per 1 kW of a solar cell.

After batteries are charged with electric power to a predetermined amount, power generated by the solar cell device is applied to a load and surplus power of the solar cell device is flowed in reverse to the utility power system.

The storage batteries may be selected from nickel metal hydride battery, nickel-cadmium battery and lithium-ion battery. The capacity of the nickel metal hydride battery may be in a range from 0.125 to 1.0 kWh per 1 kW of a solar cell.

In the present invention, as described above, storage batteries are charged with electric power generated in the morning that power demand is low and power discharged from the batteries is combined with power generated by the solar cell device to supply only at the peak period of power demand, therefore, the maximum electric power at the peak period is reduced optimally by storage batteries with small capacity.

### BRIEF DESCRIPTION OF THE DRAWINGS

FIG. 1 shows a configuration of a house installing a photovoltaic power generation system according to a first embodiment of this invention;

FIG. 2 is a block diagram showing one example of control circuit applied to the invention;

FIG. 3 shows a configuration of a house installing a photovoltaic power generation system according to a second embodiment of this invention;

FIG. 4 shows a configuration of a house installing a photovoltaic power generation system according to a third embodiment of this invention;

FIG. 5 shows a configuration of a house installing a photovoltaic power generation system according to a fourth embodiment of this invention;

FIG. 6 shows a fluctuation curve of power demand during summer in Osaka (or Tokyo) and, changes in power generation over time by the photovoltaic power generation system of 3 kW;

FIG. 7 shows a fluctuation curve of power demand and changes over time in total amount of power generated by the photovoltaic power generation system and power discharged from the storage batteries in a case where the photovoltaic power generation system in the first embodiment carries out the output control;

FIG. 8 shows a fluctuation curve of power demand and changes over time in total amount of power generated by the photovoltaic power generation system and power discharged from the storage batteries in a case where the photovoltaic power generation system in the first embodiment carries out the output control;

FIG. 9 shows changes over time in power output in a case where the peak of power output is delayed to 14:00 with two hours delay.

FIG. 10 shows changes over time in power output in a case where the peak of power output is delayed to 14:00 with two hours delay.

FIG. 11 shows a configuration of a house installing a photovoltaic power generation system according to a fifth embodiment of this invention;

FIG. 12 shows a typical load curve of electric power in Tokyo.

The foregoing and other objects, features, aspects and advantages of the present invention will become more apparent from the following detailed description of the present invention when reviewed in conjunction with the accompanying drawings.

### DESCRIPTION OF PREFERRED EMBODIMENTS

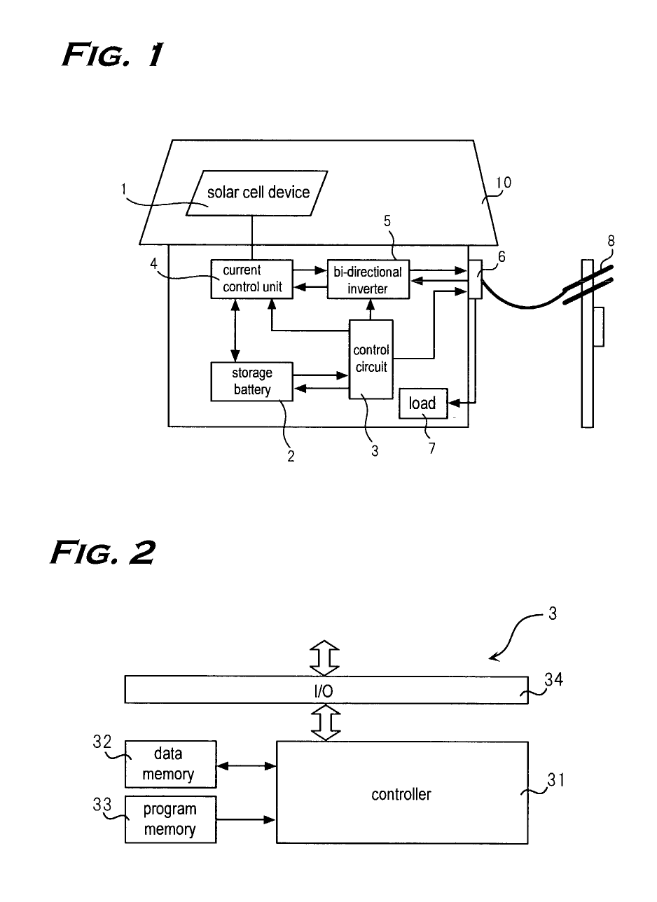

Embodiments of the present invention are now described by referring drawings below. FIG. 1 shows a configuration of a house installing the photovoltaic power generation system according to the first embodiment of the invention.

As in FIG. 1, a solar cell device 1 is set up on a roof of a house 10. The solar cell device 1 is, for example, a solar cell device whose nominal power generating capacity is 3 kW and structured by connecting a predetermined number of solar cell modules such as crystalline silicon solar cell and amorphous silicon solar cell in parallel or series. Direct current generated by the solar cell device 1 is supplied to a current control unit 4 via a switch on the direct current side (not shown). As will be described later, the current control unit 4 switches to output the direct current from the solar cell device 1 to a storage battery 2 or an inverter 5 under the control of the control circuit 3. In this embodiment, a bidirectional inverter is used as the inverter 5.

If the direct current from the solar cell device 1 is supplied to the storage battery unit 2, storage batteries in the storage battery unit 2 are charged. If the direct current from the solar cell device 1 is supplied to the inverter 5, the direct current is converted into alternating current in the inverter 5 and the alternating current is applied to a load 7 in the house from an electric system such as an outlet via a panel board 6.

Power is also supplied to the electric system of the house from the utility power system 8 through the panel board 6. When power from the solar cell device 1 is insufficient at night, the power from the utility power system 8 can be utilized.

The inverter 5 also has a function of converting alternating current fed from the utility power system 8 into direct current so that the power from the utility power system 8 can be supplied to charge the storage battery unit 2 via the current control unit 4.

The storage battery unit 2 comprises a charging and discharging circuit (not shown) so that the storage batteries are charged or discharge depending on the fed direct current. The control circuit 3 controls the charge and discharge of the storage battery unit 2 on the basis of signal of voltage, etc. given from the storage battery unit 2.

The control circuit 3 controls operations of the current control unit 4, the storage battery unit 2, the inverter 5, the panel board 6 and so on.

In a case where power is generated by the solar cell device 1 more than the load consumed at home, the photovoltaic power generation system lets the surplus power flow in reverse to the utility power system 8 to sell the surplus power to an electric power company. Also in a case where power failure occurs at the utility power system 8, the photovoltaic power generation system supplies power from the solar cell device 1 to operate home electric appliances.

In the photovoltaic power generation system of the present invention, the storage battery unit 2 is charged with power generated in the morning when power demand is low under the control of the control circuit 3. The control circuit 3 controls charge and discharge of the storage battery unit 2 so that power discharged from the storage battery unit 2 is added to the power generated by the solar cell device 1 only when power demand reaches its peak.

FIG. 2 shows one example of a structure of the control circuit 3 which comprises a controller 31 including CPU or the like, data memory 32, program memory 33, and an I/O 34. The controller 31 controls each circuit on the basis of programs stored in the program memory 33. The data memory 32 stores data of a fluctuation curve of power demand by weather information of each season including temperature and humidity, and region.

As described above, the fluctuation curve of power demand varies according to various parameters such as season, temperature and region, especially in a time period of peak demand and a total amount of power generated and purchased. The data memory 32 stores these data.

Especially in this embodiment, the controller 31 controls the charging start time and stop time of the storage battery unit 2, the discharging start time of the storage battery unit 2, an amount of discharged power and the discharging period by referring to data based on the fluctuation curve of power demand which are stored in data memory 32. The controller 31 feeds various control signals from the I/O 34 to each circuit. The data from the circuit are fed to the controller 31 via the I/O 34, and the data memory 32 stores only the essential data.

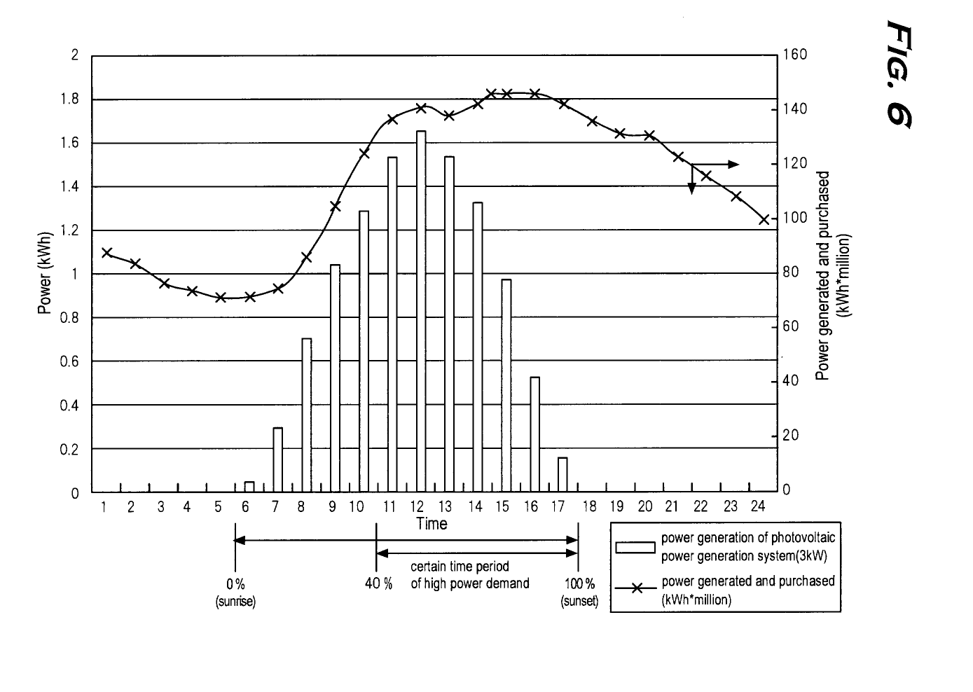

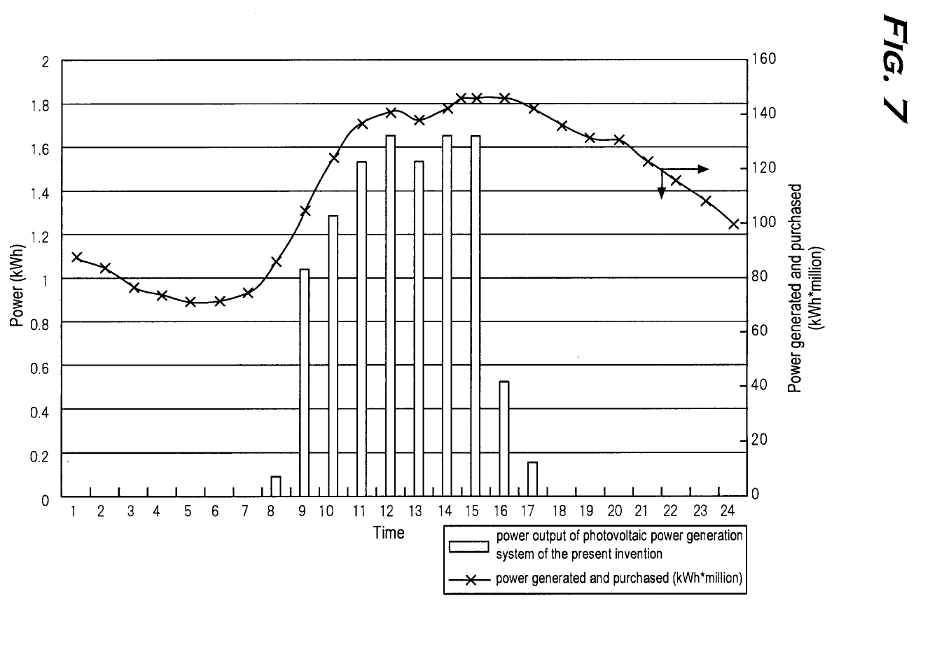

Further the first embodiment of the present invention is described by referring to FIGS. 6 to 8. FIG. 6 shows a fluctuation curve of power demand in summer in Osaka (or Tokyo) and changes in power generation over time by the photovoltaic power generation system of 3 kW. In FIG. 6, we assume that sunrise is 0% and sunset is 100% when the time range between sunrise and sunset is expressed as a percent. The power generation by the photovoltaic power generation system is peaked from 12:00 to 13:00. There is a delay of approximately two hours before the power demand reaches its peak. The time period in which power is demanded most is equivalent to 40 to 100%, given that sunrise is 0% and sunset is 100% when the time range between sunrise and sunset is expressed as a percent.

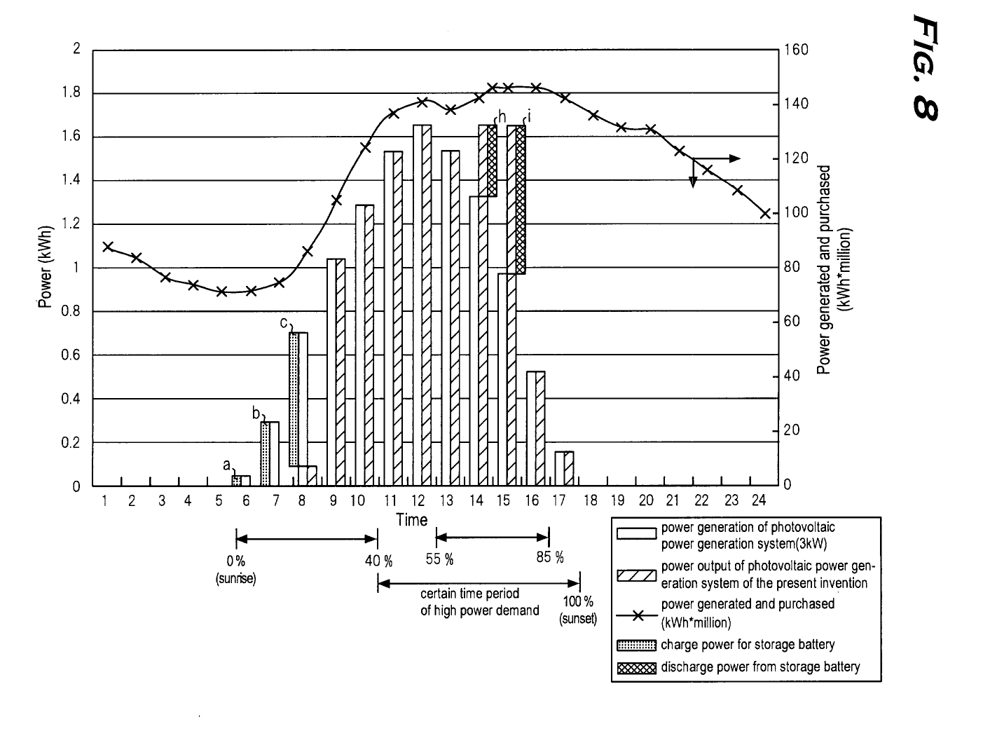

FIG. 7 shows a result of which the photovoltaic power generation system of the first embodiment of the invention carries out the output control in the state where power is generated under the condition of the solar radiation indicated in FIG. 6. In other words, FIG. 7 shows a fluctuation curve of power demand and changes over time in electric power output which is controlled by the photovoltaic power generation system. As shown in FIG. 7, the storage battery unit 2 is charged with electric power generated by the solar cell device 1 in the early morning and discharges the stored power from 14:00 to 16:00 to output along with power generated by the solar cell device 1 to meet power demand from 14:00 to 16:00. As apparent from FIG. 7, electric power from the photovoltaic power generation system can effectively cover most time periods of high power demand.

This state is further described by referring to FIG. 8. The bars with a hatched pattern in FIG. 8 represent an amount of output power under the control of the photovoltaic power generation system in this embodiment of the present invention. The solid white bars represent an amount of power generated by the photovoltaic power generation system.

In this embodiment, the control circuit 3 controls the charge and discharge of the storage battery unit 2 so as to charge electric power generated by the solar cell device 1 in the early morning and to discharge the stored power from 14:00 to 16:00.

In the embodiment shown in FIG. 8, the solar cell device 1 generates power indicated by the solid white bars from sunrise (05:30) to 11:00. The generated power is supplied to charge the storage battery unit 2. The control circuit 3 controls the current control unit 4 to feed direct current from the solar cell device 1 to charge the storage battery unit 2. The bars with a dotted pattern in FIG. 8 represent an amount of electric power charged in the storage battery unit 2. Of power indicated by solid white bars, the power indicated by dotted patterned bars a, b, and c is stored in the storage battery unit 2.

In this embodiment, the storage battery is supposed to be fully charged with electric power of 0.96 kWh. The control circuit 3 monitors the voltage of the storage battery unit 2 so as to control the current control unit 4 to supply direct current from the solar cell device 1 to the inverter 5 when the storage batteries complete charging.

Although the photovoltaic power generation system of the embodiment in FIG. 8 is set to charge batteries until 11:00, which is before power demand reaches its peak, the control circuit 3 controls the current control unit 4 to supply power from the solar cell device 1 to the inverter 5 because the storage batteries complete charging before 9:00. The power represented by a, b, and c in FIG. 8 is charged in the storage battery unit 2. In a case where the storage battery unit 2 does not complete charging until 11:00 for lack of solar radiation, the control circuit 3 suspends the charge for the storage battery unit 2 and controls the current control unit 4 to supply power from the solar cell device 1 to the inverter 5.

As a storage battery, it is favorable to use a nickel metal hydride battery, a nickel cadmium battery or a lithium-ion battery. These batteries have their own features and should be chosen in consideration of end-use condition. As will be shown in a table later, a lead-acid battery is unfavorable for use in this invention because it requires a large capacity.

The control circuit 3 controls the solar cell device 1 to supply power to the inverter 5 until 14:00 and the storage battery 2 to discharge power at the maximum peak demand of 14:00. In this embodiment, the storage battery unit 2 is controlled to discharge power for two hours between 14:00 to 16:00 and the power discharged from the storage battery unit 2 is combined with the power generated by the solar cell device 1 to supply to the inverter 5. The bars with a grid pattern h and i in FIG. 8 represent discharge power from the storage battery unit 2. During 14:00 to 16:00, the discharge power indicated with the grid patterned bars h and i is added to the power generated by the solar cell device 1 to output as the combined power indicated with hatched patterned bars. All the power stored in the storage battery unit 2 is discharged within two hours.

The time period in which electric power is discharged from the storage battery 2 to combine with power generated by the solar cell device 1 is at the off-peak period of power generation of the solar cell device 1 as well as the peak period of power demand. Given that sunrise is 0% and sunset is 100% when the time range between sunrise and sunset is expressed as a percent, such a period of time is in a range from 55 to 85%.

The photovoltaic power generation device can control an amount of the charging power for the storage batteries so that the total amount of power generated by the solar cell device and power discharged from the storage batteries at the peak period of power demand is equivalent to or more than the amount of power generated by the solar cell device 1 until the time represented by 55%, given that sunrise is 0% and sunset is 100% when the time range between sunrise and sunset is expressed as a percent.

After the discharge of the storage battery unit 2 is completed, the control circuit 3 controls the current control unit 4 to supply only power from the solar cell device 1 to the inverter 5.

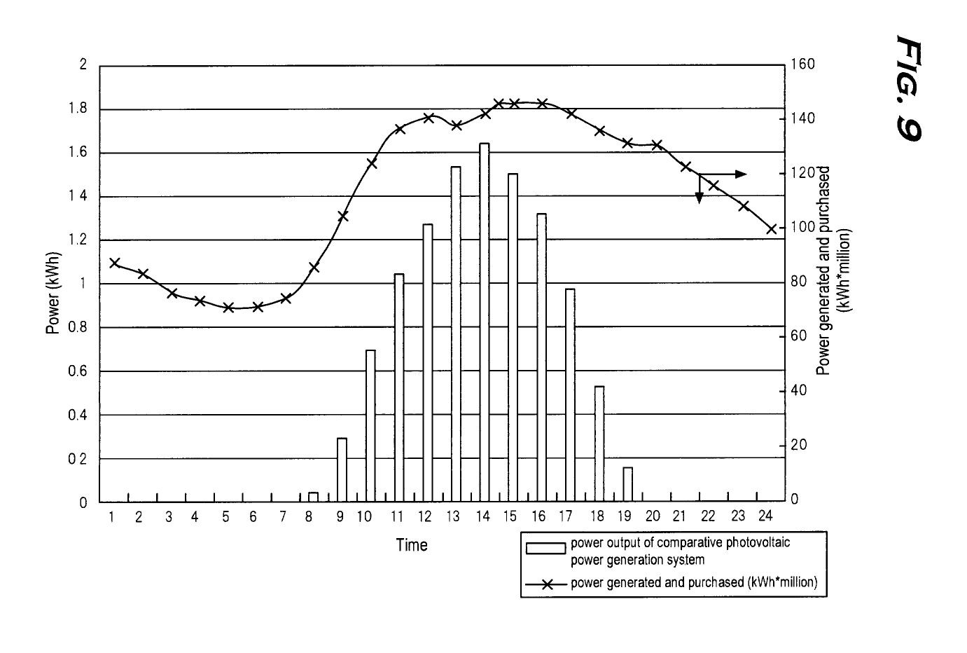

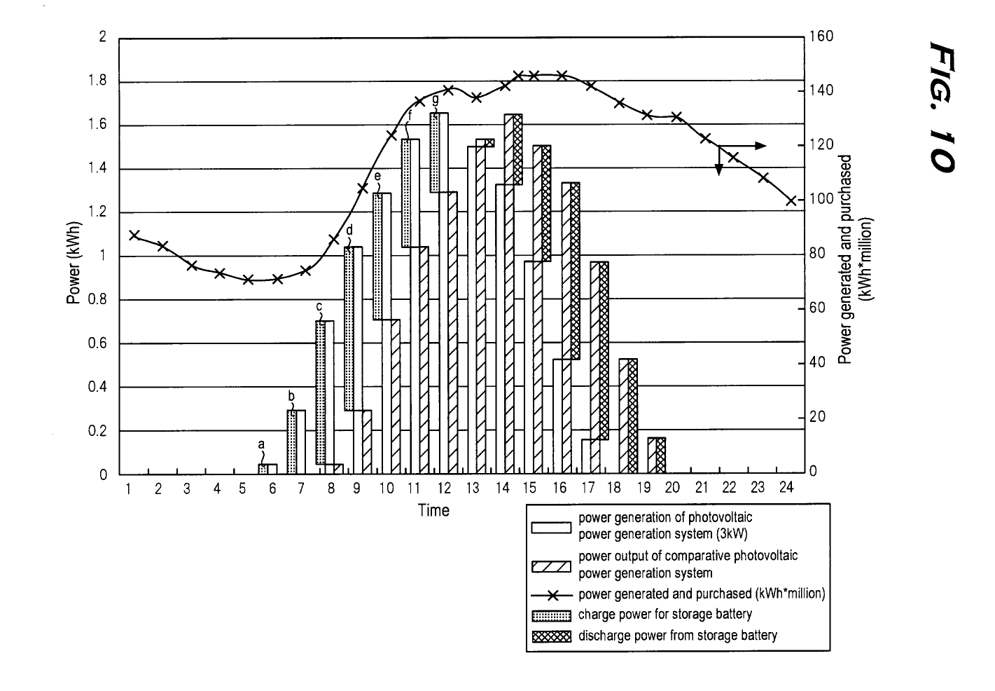

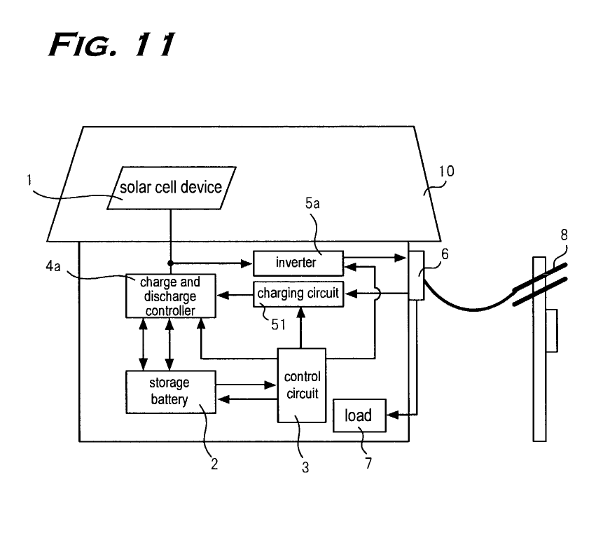

A comparison is made between the control system of the present invention and another system that outputs solar power with a predetermined time delay, for example, two hours delay. FIG. 9 shows a fluctuation curve of power demand and changes in power generation over time by the photovoltaic power generation system in a case where time schedule of power generation shown in FIG. 6 is delayed for two hours, thereby being the peak period of power generation at 14:00. Further description on the comparative output control system is made by referring to FIG. 10.

The bars with a hatched pattern represent output power which is controlled the output with a two-hour delay (same as solid white bars in FIG. 9). The solid white bars represent an amount of power generated by the photovoltaic power generation system. The bars with a dotted pattern represent an amount of power charged in the storage battery unit 2. The bars with a grid pattern represent an amount of power discharged from the storage battery unit 2. As apparent from the FIG. 10, the storage battery unit 2 is charged from sunrise to 12:00 and starts discharging from 13:00. Specifically the power a generated from 6:00 to 7:00 and the power b generated from 7:00 to 8:00 are all charged in the storage battery unit 2. The power c, which is obtained by subtracting power generated from 6:00 to 7:00 from the power generated from 8:00 to 9:00 that is two hours after 6:00 to 7:00, is charged in the storage battery unit 2. In the same way, with a two-hour delay of power generation, the power e to g, which is more than each power generated two hours ago, is charged in the storage battery unit 2. In this example, the power a to g is charged in the storage battery unit 2 from sunrise to 12:00, therefore the batteries need a capacity of 3.16 kWh, which means the batteries must have a large capacity. As indicated with the grid patterned bars, power discharged from the storage batteries is added to power generated by the solar cell device 1 so that power generated by the solar cell device 1 is output with a two-hour delay.

As is apparent from FIG. 10, about one-third of power generated by the solar cell device 1 is used for charging the storage batteries even at 12:00 when power demand becomes high. It is a problem that all power generated by the solar cell device 1 cannot be used while power demand is high.

In table 1 below, a photovoltaic power generation system applying output control of the present invention shown in FIG. 7 and the above comparative system with a two-hour delay are compared by noting battery capacity. Here, a nickel metal hydride battery and a lead-acid battery are used as a storage battery.

| | comparative example | | present invention | |
|---|---|---|---|---|
| time | the peak period of power | | power generated from 6:00 to | |
| schedule | generation is delayed for 2 | | 9:00 is charged and | |
| | hours, being at 14:00 | | discharged the stored power | |
| | | | from 14:00 to 16:00 | |
| operating | 7-hour charge (0.01-0.24 C.) | | 3-hour charge (0.04-0.65 C.) | |
| required | 3.16 | | 0.96 | |
| capacity | | | | |
| battery | NiMH | Pb | NiMH | Pb |
| type | | | | |
| capacity | 3.95 | 7.90 | 1.20 | 2.40 |
| (kWh) | | | | |

According to table 1, the photovoltaic power generation system of the present invention can carry out optimal output control with small capacity storage batteries. Also a nickel cadmium battery and a lithium-ion battery are suitable for the system of our invention.

Although, in the above mentioned embodiment, the storage battery unit 2 discharges power, which is generated and fed by the solar cell device 1, for two hours, the storage battery unit 2 can also discharge power, which is charged previously supplied from the utility power system 8 at night, to combine with power generated by the solar cell device 1 until 16:00, specifically from 15:00 to 16:00. In this case the storage battery unit 2 can discharge power for three hours without increasing the charging time from the solar cell device 1, but the capacity of the storage battery unit 2 should be correspondingly large.

Although the above mentioned embodiment shows an example in which charge and discharge are controlled on the basis of the fluctuation curve of power demand in summer in Osaka (or Tokyo), optimal charge and discharge can be carried out in accordance with a fluctuation curve of power demand of other seasons and other regions. In Hokkaido, for example, the control circuit 3 may be optimized to control charge and discharge in accordance with a fluctuation curve of power demand (e.g. the storage battery starts discharging at 15:00 or 16:00).

The photovoltaic power generation system of 3 kW in this embodiment generates 1.65 kWh of power from 12:00 to 13:00 when the amount of solar radiation is largest, but generates 1.32 kWh of power from 14:00 to 15:00, therefore the storage batteries needs to discharge 0.33 kWh of power (=1.65−1.32) from 14:00 to 15:00. Consequently, the storage battery preferably should have more capacity than 0.1 kWh (=0.33/3) per 1 kW of a solar cell.

On the other hand, the storage battery unit 2 must discharge 2.18 kWh totally (=0.12(13:00-14:00)+0.3(14:00-15:00)+0.66(15:00-16:00)+1.1(16:00-17:00)) in the period of time from 55% to 85% that power discharged from the storage battery unit 2 is combined with power generated by the solar cell device 1, in order to obtain power that is the same as the largest amount of electric power which the solar cell device 1 generates during the period of time from 55% to 85%. Consequently a storage battery should have the capacity of 0.73 kWh per 1 kW of a solar cell to satisfy the value 2.18 kWh. If the storage battery has a capacity less than 0.8 kWh, this invention can produce a sufficient effect. On the contrary it is not favorable to use the storage battery of more than 0.8 kWh because such a battery and a control circuit are costly.

The nickel metal hydride battery should be favorably charged and discharged at 0 to 80% depth of charge in consideration of its service life. Therefore, the rated capacity of the nickel metal hydride battery used in the present system would be in a range between 0.125(=0.1/80×100) and 1(=0.8/80×100).

A second embodiment of the present invention is now described by referring to FIG. 3. Although the storage battery unit 2 is charged with power generated by the solar cell device 1 in the early morning in the first embodiment, it sometimes occurs that the solar cell device 1 can not generate sufficient power for the storage battery unit 2 due to insufficient solar radiation on a cloudy day. In the second embodiment, the storage battery unit 2 is charged with nighttime power from a utility power system 8 depending on the weather conditions of the next day obtained by a weather forecast. As shown in FIG. 3, a weather forecast provider 9 provides information including the following day's weather, temperature etc. by time to each house 10 through an exchange 92 on Internet 91. Weather information from the weather forecast provider 9 is supplied through a communication line 93 and stored in data memory of a control circuit 3 in the house 10. The control circuit 3 predicts whether sufficient power will be available tomorrow or not on the basis of the weather forecast information and whether power will be consumed at great deal or not under the weather condition including temperature or the like. If the control circuit 3 judges that power from the storage battery unit 2 is required at the maximum peak period of power demand and it is impossible to charge the storage battery unit 2 within a predetermined charging time based on the forecast of solar radiation, the control circuit 3 controls a panel board 6, an inverter 5, a current control unit 4 to charge the storage battery unit 2 with nighttime power from the utility power system 8 to cover the shortfall. By considering the weather forecast information, power for the next day's maximum peak demand can be reserved with low-cost nighttime power.

Also the photovoltaic power generation system of the present invention can control the discharging start time of the storage battery unit 2 and an amount of power to be charged in the storage battery unit 2 by predicting the peak period of power demand on the basis of information from the weather forecast provider 9.

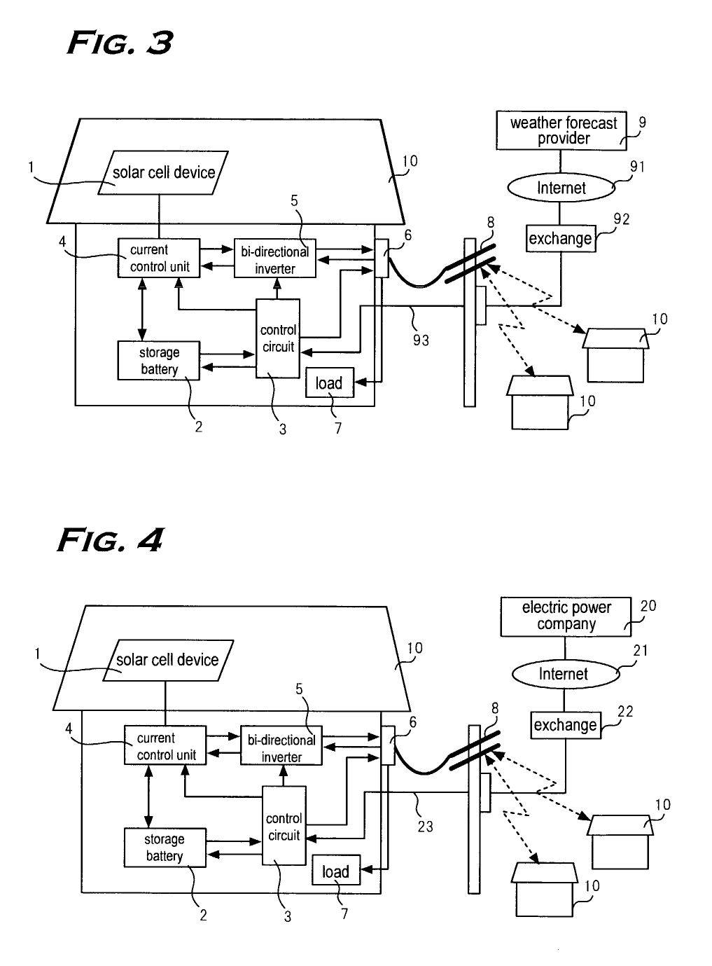

A third embodiment of the present invention is now described by referring to FIG. 4. Although the storage battery unit 2 is charged with nighttime power from the utility power system 8 according to weather information obtained from the weather forecast provider 9 in the above second embodiment, the photovoltaic power generation system in the third embodiment obtains information regarding peak demand for the next day from an electric power company 20. The information regarding peak demand from the electric power company 20 is fed to an exchange 22 through Internet 21 and stored in data memory of a control circuit 3 in the house 10 via a communication line 23. The control circuit 3 predicts an amount of charging power and discharging power of the storage battery unit 2 on the basis of information of peak demand. If the control circuit 3 judges that the storage battery unit 2 is required to discharge power at the predicted maximum peak period of power demand and it is impossible to charge the storage battery unit 2 within a predetermined charging time, the control circuit 3 controls a panel board 6, an inverter 5, a current control unit 4 to charge the storage battery unit 2 with nighttime power from the utility power system 8 to cover the shortfall. By considering the information of peak demand provided by the electric power company 20, power for the next day's maximum peak demand can be reserved with low-cost nighttime power.

Also the photovoltaic power generation system of the present invention can control the discharging start time of the storage battery unit 2 and an amount of power to be charged in the storage battery unit 2 on the basis of information from the electric power company 20.

Although data are transmitted via the exchange 22 in the above embodiment, a power line can be commonly used for data transmission.

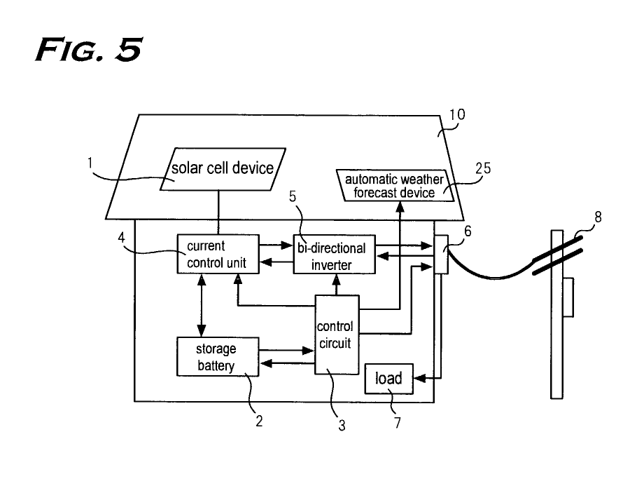

A fourth embodiment of the present invention is now described by referring to FIG. 5. Although the storage battery unit 2 is charged with nighttime power from the utility power system 8 according to weather information obtained from the weather forecast provider 9 in the second embodiment, the storage battery unit 2 in the fourth embodiment is charged with nighttime power from the utility power system 8 by installing an automatic weather forecast device 25 in a house and considering weather conditions for the next day predicted by the automatic weather forecast device 25. Weather information including weather, temperature etc. by time for the next day provided from the automatic weather forecast device 25 is stored in data memory of the control circuit 3. The control circuit 3 predicts whether sufficient power will be available tomorrow or not on the basis of the weather forecast information and whether power will be consumed at great deal or not under the conditions such as temperature. If the control circuit 3 judges that power from the storage battery unit 2 is required at the maximum peak period of power demand and it is impossible to charge the storage battery unit 2 within a predetermined charging time based on the forecast of solar radiation, the control circuit 3 controls a panel board 6, an inverter 5, a current control unit 4 to charge the storage battery unit 2 with nighttime power from the utility power system 8 to cover the shortfall. By considering the weather forecast information, power for the next day's maximum peak demand can be reserved with low-cost nighttime power.

Also the photovoltaic power generation system of the present invention can control the discharging start time of the storage battery unit 2 and an amount of power to be charged in the storage battery unit 2 by predicting the peak period of power demand on the basis of information from the automatic weather forecast device 25.

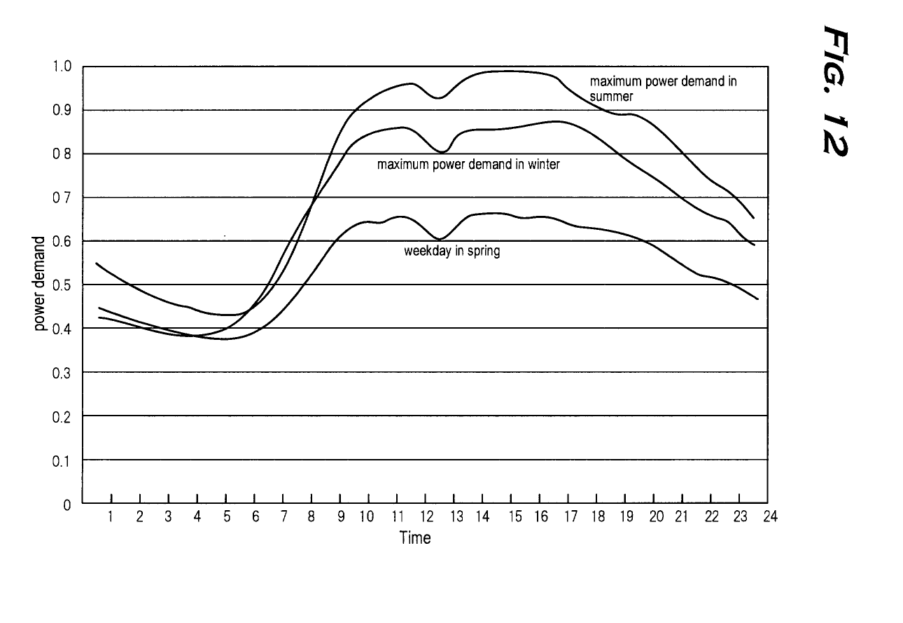

In the first embodiment to fourth embodiment, a bi-directional inverter is used as the inverter 5. A fifth embodiment, which uses a general inverter, is now described by referring to FIG. 11. FIG. 11 shows the same configuration as the first embodiment with a general inverter.

FIG. 11 shows a house 10, which installs a solar cell device 1 on the roof. The solar cell device 1 is a solar cell device whose nominal power generating capacity is 3 kW and structured by connecting a predetermined number of solar cell modules such as crystalline silicon solar cell and amorphous silicon solar cell in parallel or series. Direct current generated in the solar cell device 1 is supplied to an inverter 5a and a charge and discharge controller 4a via a switch on the direct current side (not shown). As will be described later, the charge and discharge controller 4a feeds the direct current from the solar cell device 1 to charge a storage battery 2 under the control of a control circuit 3 and feeds discharging power from the storage battery 2 to the inverter 5a. In this embodiment, a charging circuit 51, which converts alternating current supplied from a utility power system 8 into direct current, is comprised so that the direct current from the charging circuit 51 is supplied to the storage battery unit 2 via the charge and discharging controller 4a to charge storage batteries of the storage battery unit 2.

When the direct current from the solar cell device 1 is supplied to the storage battery unit 2 through the charge and discharge controller 4a, the storage batteries in the storage battery unit 2 are charged. When the direct current from the solar cell device 1 is supplied to the inverter 5a, the direct current is converted into alternating current by the inverter 5a and the alternating current is supplied to an electric system such as a plug in the house via the panel board 6 to power the load 7 in the house.

Power is also supplied from the utility power system 8 to the electric system in the house via the panel board 6. When power supplied from the solar cell device 1 is insufficient at night, power from the utility power system 8 is utilized.

The control circuit 3 controls charge and discharge of the storage battery unit 2 on the basis of a signal such as a voltage or the like given from the storage battery unit 2.

The control circuit 3 controls operations of the charge and discharge controller 4a, the storage battery unit 2, the inverter 5a, the panel board 6 and so on.

In a case where power is generated by the solar cell device 1 more than the load consumed at home, the photovoltaic power generation system lets the surplus power flow in reverse to the utility power system 8 to sell the surplus power to an electric power company. Also in a case where power failure occurs at the utility power system 8, the photovoltaic power generation system supplies power from the solar cell device 1 to operate home electric appliances.

In the photovoltaic power generation system of the present invention, the storage battery unit 2 is charged with power generated in the morning when power demand is low under the control of the control circuit 3. The control circuit 3 controls charging and discharging of the storage battery unit 2 so that power discharged from the storage battery unit 2 is added to the power generated by the solar cell device 1 only when power demand reaches its peak.

Further a fifth embodiment of the present invention is described. Like the first embodiment, power generated by the solar cell device 1 in the early morning is charged in the storage battery unit 2, the power stored in the storage battery unit 2 is discharged from 14:00 to 16:00 and added to the power generated by the solar cell device 1 to meet power demand from 14:00 to 16:00 (see FIG. 7).

In the fifth embodiment, the control circuit 3 controls charge and discharge of the storage battery unit 2 so as to charge power generated by the solar cell device 1 in the early morning and to discharge the stored power from 14:00 to 16:00.

Power, which is generated by the solar cell device 1 from sunrise (5:30) to 11:00, is supplied to the storage battery unit 2 through the charge and discharge controller 4a and to the inverter 5a in parallel. The control circuit 3 suspends the inverter 5a to drive until the storage battery unit 2 is charged to a predetermined amount. Power generated by the solar cell device 1 is supplied to charge the storage battery unit 2.

In this embodiment, the storage battery is supposed to complete charging with electric power of 0.96 kWh. The control circuit 3 monitors the voltage and so on of the storage battery unit 2. After the completion of charging the storage batteries in the storage batteries unit 2 or just before the completion, the control circuit 3 starts driving the inverter 5a to convert direct current from the solar cell device 1 into alternating current.

Even though the storage battery unit 2 is not fully charged until 11:00 for lack of solar radiation, the control circuit 3 suspends the charge for the storage battery unit 2 and controls the solar cell device 1 to supply all power to the inverter 5a.

The only power generated by the solar cell device 1 is fed to the inverter 5 until 14:00 under the control of the control circuit 3. At the peak period of 14:00, the storage battery unit 2 starts discharging power. In this embodiment, the storage battery unit 2 is so controlled as to discharge power for two hours between 14:00 and 16:00 to supply to the inverter 5a along with power generated by the solar cell device 1. All power stored in the storage battery unit 2 is discharged within two hours.

When the storage battery unit 2 completes discharging, the inverter 5a converts power from the solar cell device 1 into alternating current and outputs it.

In a case where the storage battery unit 2 is charged with nighttime power, the control circuit 3 controls the panel board 6, the charging circuit 51 and the charge and discharge controller 4a to charge the storage battery unit 2 with nighttime power. Therefore, the storage battery unit 2 can reserve power by using low-cost nighttime power to discharge and combine with power from the solar cell device 1 at the peak period of power demand.

Like the fifth embodiment, the photovoltaic power generation system in the second to fourth embodiments also may comprise the general inverter.

As explained above, the present invention can provide a photovoltaic power generation system capable of controlling the power output in reference to peak demand for power with small capacity battery and reducing commercial power consumption optimally at the peak period of power demand. Also the photovoltaic power generation system can readily control the power output suitable for regions, seasons and so on.

Although the present invention has been described and illustrated in detail, it should be clearly understood that the description discloses examples of different embodiments of the invention and is not intended to be limited to the examples or illustrations provided. Any changes or modifications within the spirit and scope of the present invention are intended to be included, the invention being limited only by the terms of the appended claims.

What we claim is;

1. A photovoltaic power generation system with storage batteries comprising:
a solar cell device;
an inverter which converts a direct current generated by the solar cell device into an alternating current;
a device for supplying the alternating current to a power consumption section;
storage batteries which store electric power;
a switch control device for switching to output electric power from the solar cell device to the storage batteries or the inverter;
a power control device for controlling discharge of power stored in the storage batteries in accordance with a certain time period of high power demand represented by a fluctuation curve of power demand and supplying power from the storage batteries along with power generated by the solar cell device to the inverter

2. A photovoltaic power generation system with storage batteries according to claim 1 wherein,
the storage batteries are charged with electric power which is generated by the solar cell device during the off-peak period of power demand after sunrise.

3. A photovoltaic power generation system with storage batteries according to claim 1 wherein,
the certain time period in which power demand is high is in a region from 40 to 100%, given that sunrise is 0% and sunset is 100% when the time range between sunrise and sunset is expressed as a percent.

4. A photovoltaic power generation system with storage batteries according to claim 1 wherein,
the time period in which electric power is discharged from the storage batteries and combined with power generated by the solar cell device is the off-peak period of power generation of the solar cell device as well as the peak period of power demand and in a range from 55 to 85%, given that sunrise is 0% and sunset is 100% when the time range between sunrise and sunset is expressed as a percent.

5. A photovoltaic power generation system with storage batteries according to claim 1 wherein,
the storage battery is selected from a nickel metal hydride battery, a nickel-cadmium battery and a lithium-ion battery.

6. A photovoltaic power generation system with storage batteries according to claim 5 wherein,
a capacity of the nickel metal hydride battery is in a range from 0.125 to 1.0 kWh per 1 kW of a solar cell.

7. A photovoltaic power generation system with storage batteries comprising:
a solar cell device;
an inverter which converts a direct current generated by the solar cell device into an alternating current;
a device for supplying the alternating current, which converted by the inverter, to a power consumption section, and which links with a utility power system;
storage batteries which store electric power;
a switch control device for switching to output electric power from the solar cell device to the storage batteries or the inverter;
a charging control device for controlling the storage battery to charge with electric power selected either from electric power generated by a solar cell device at the off-peak period of power demand after sunrise, electric power supplied from the utility power system during the night, or both;
a power control device for controlling discharge of power stored in the storage batteries in accordance with a certain time period of high power demand represented by a fluctuation curve of power demand and supplying power from the storage batteries along with power generated by the solar cell device to the inverter.

8. A photovoltaic power generation system with storage batteries according to claim 7 wherein,
the certain time period in which power demand is high is in a region from 40 to 100%, given that sunrise is 0% and sunset is 100% when the time range between sunrise and sunset is expressed as a percent.

9. A photovoltaic power generation system with storage batteries according to claim 7 wherein,
the time period in which electric power is discharged from the storage batteries and combined with power generated by the solar cell device is the off-peak period of power generation of the solar cell device as well as the peak period of power demand and in a range from 55 to 85%, given that sunrise is 0% and sunset is 100% when the time range between sunrise and sunset is expressed as a percent.

10. A photovoltaic power generation system with storage batteries according to claim 7 wherein,
charging control means control an amount of the charging power for the storage batteries so that the total amount of power generated by the solar cell device and power discharged from the storage batteries at the peak period of power demand is approximately equivalent to or more than the maximum amount of power generated by the solar cell device until the time represented by 55%, given that sunrise is 0% and sunset is 100% when the time range between sunrise and sunset is expressed as a percent.

11. A photovoltaic power generation system with storage batteries according to claim 7 wherein,
the certain time period in which the storage batteries are charged within the off-peak period of power demand is in a region from 0 to 40%, given that sunrise is 0% and sunset is 100% when the time range between sunrise and sunset is expressed as a percent.

12. A photovoltaic power generation system with storage batteries according to claim 7 wherein,
a capacity of the storage battery for constant use is in a range from 0.1 to 0.8 kWh per 1 kW of a solar cell.

13. A photovoltaic power generation system with storage batteries according to claim 7 wherein,
power generated by the solar cell device is applied to a load after the storage batteries are charged to the predetermined amount and the surplus power is flowed in reverse to the utility power system.

14. A photovoltaic power generation system with storage batteries according to claim 7 wherein,
the storage battery is selected from a nickel metal hydride battery, a nickel-cadmium battery and a lithium-ion battery.

15. A photovoltaic power generation system with storage batteries according to claim 14 wherein,
a capacity of the nickel metal hydride battery is in a range from 0.125 to 1.0 kWh per 1 kW of a solar cell.
